(19) United States
(12) Patent Application Publication
(10) Pub. No.: US 2015/0346601 A1
(43) Pub. Date: Dec. 3, 2015

(54) PHOTOSENSITIVE POLYSILOXANE COMPOSITION, PROTECTIVE FILM AND ELEMENT HAVING THE PROTECTIVE FILM

(71) Applicant: Chi Mei Corporation, Tainan City (TW)

(72) Inventors: Ming-Ju Wu, Tainan City (TW); Chun-An Shih, Tainan City (TW)

(21) Appl. No.: 14/825,175

(22) Filed: Aug. 13, 2015

Related U.S. Application Data
(63) Continuation-in-part of application No. 14/254,904, filed on Apr. 17, 2014, now abandoned.

(30) Foreign Application Priority Data
Apr. 26, 2013 (TW) 102115068

(51) Int. Cl. G03F 7/075; G03F 7/16

(52) U.S. Cl. CPC G03F 7/0757; G03F 7/16

(57) ABSTRACT

A photosensitive polysiloxane composition including a nitrogen-containing heterocyclic compound (A), a polysiloxane (B), an o-naphthoquinone diazide sulfonate (C), and a solvent (D) is provided. The nitrogen-containing heterocyclic compound (A) is selected from the group consisting of compounds represented by formulas (1) to (4):

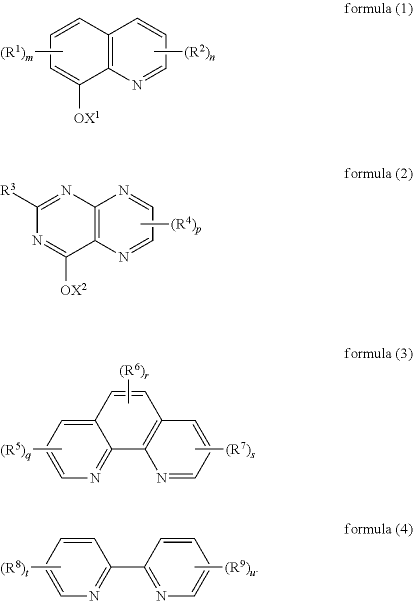

### CROSS-REFERENCE TO RELATED APPLICATION

This application is a continuation-in-part application of and claims the priority benefit of U.S. application Ser. No. 14/254,904, filed on Apr. 17, 2014, now pending. The prior U.S. application Ser. No. 14/254,904 claims the priority benefit of Taiwan application serial no. 102115068, filed on Apr. 26, 2013. The entirety of each of the above-mentioned patent applications is hereby incorporated by reference herein and made a part of this specification.

### BACKGROUND OF THE INVENTION

1. Field of the Invention

The present invention generally relates to a polysiloxane composition. More particularly, the present invention relates to a photosensitive polysiloxane composition.

2. Description of Related Art

In recent years, following the development of the semiconductor industry, liquid crystal displays (LCDs) and organic electro-luminescence displays (OELDs), the demand of size reduction arises and the photolithography processes become very important issues. In the photolithography process, the miniaturization of the pattern(s) is required to achieve the purpose of size reduction. Generally, the miniaturized pattern is formed by exposing and developing the positive photosensitive composition having a high resolution and high photosensitivity. It is noted that polysiloxane is usually the main component of the positive photosensitive composition.

Japanese Laid-Open No. 2008-107529 discloses a photosensitive composition for a hardened film of a high degree of transparency. The photosensitive composition includes polysiloxane, in which the polysiloxane is copolymerized by silane monomers containing oxetanyl or oxydicarbonyl groups. The photosensitive composition with a hydrophilic structure has a high solubility in the weak alkaline developer. However, the adhesion and the taper angle between the protective film formed of such photosensitive resin composition and the device to be protected are poor, leading to limited applications.

It is desirable to develop a photosensitive composition to provide good adhesion property between the formed protective film and the device.

### SUMMARY OF THE INVENTION

This invention relates to a photosensitive polysiloxane composition, which can provide good adhesion and a satisfactory taper angle as a protective film formed between the elements or devices to be protected.

The present invention provides a photosensitive polysiloxane composition comprising a nitrogen-containing heterocyclic compound (A), polysiloxane (B), o-naphthoquinone diazide sulfonate (C) and a solvent (D). The nitrogen-containing heterocyclic compound (A) is selected from the group consisting of compounds represented by formula (1) to formula (4):

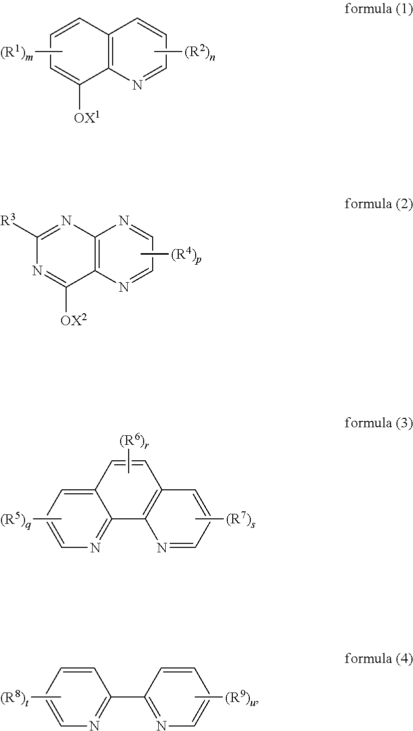

wherein in the formulae (1) to (4), X¹ and X² each independently represents hydrogen, an acyl or an alkyl group; R¹ to R⁹ each independently represents hydrogen, a hydroxyl group, a carboxyl group (—COOH), a sulfo group (—SO₃H), an alkyl group, an amino group, halogen or a mercapto group (—SH); m, n, q and s each independently represents an integer selected from 0, 1, 2 and 3; p and r each independently represents an integer selected from 0, 1 and 2; t and u each independently represents an integer selected from 0, 1, 2, 3 and 4. The polysiloxane (B) is a copolymer formed by polycondensation of a mixture, and the mixture comprises a silane monomer (b-1) of the formula (5), a silane monomer (b-2) of the formula (7), and a silane monomer (b-3) of the formula (8):

Si(R¹⁰)_{w}(OR¹¹)_{4-w} formula (5),
wherein, in the formula (5), R¹⁰ represents hydrogen, an alkyl group of 1-10 carbon atoms, an alkenyl group of 2-10 carbon atoms, an aryl group of 6-15 carbon atoms, an alkyl group containing an acid anhydride group, an alkyl group containing an epoxy group, an alkoxy group containing an epoxy group, and R¹⁰ comprises at least one alkyl group containing an acid anhydride group, and for more than one R¹⁰, R¹⁰ may be the same or different; R¹¹ represents hydrogen, an alkyl group of 1-6 carbon atoms, an acyl group of 1-6 carbon atoms, an aryl group of 6-15 carbon atoms, and for more than one R¹¹, R¹¹ may be the same or different; w represents an integer selected from 1, 2 and 3;

Si(R⁷⁰)ᵥ(OR⁷¹)₄₋ᵥ formula (7),
wherein, in the formula (7), R⁷⁰ represents hydrogen, an alkyl group of 1-10 carbon atoms, an alkenyl group of 2-10 carbon atoms, an aryl group of 6-15 carbon atoms, an alkyl group containing an acid anhydride group, an alkyl group containing an epoxy group, an alkoxy group containing an epoxy group, and R⁷¹ comprises at least one alkyl group containing an epoxy group or an alkoxy group containing an epoxy group, and for more than one R⁷⁰, R⁷⁰ may be the same or different; R⁷¹ represents hydrogen, an alkyl group of 1-6 carbon atoms, an acyl group of 1-6 carbon atoms, an aryl group of 6-15 carbon atoms, and for more than one R⁷¹, R⁷¹ may be the same or different; v represents an integer selected from 1, 2 and 3; and

Si(R⁸⁰)_{f}(OR⁸¹)_{4-f} formula (8),
wherein, in the formula (8), R⁸⁰ represents hydrogen, an alkyl group of 1-10 carbon atoms, an alkenyl group of 2-10 carbon atoms, an aryl group of 6-15 carbon atoms, and for more than one R⁸⁰, R⁸⁰ may be the same or different; R⁸¹ represents hydrogen, an alkyl group of 1-6 carbon atoms, an acyl group of 1-6 carbon atoms, an aryl group of 6-15 carbon atoms, and for more than one R⁸¹, R⁸¹ may be the same or different; f represents an integer selected from 0, 1, 2 and 3.

In one embodiment of the present invention, for the photosensitive polysiloxane composition, relative to the total content of the silane monomers in the mixture as 1.0 mole, the content of the silane monomer (b-1) is 0.01 moles to 0.20 moles; the content of the silane monomer (b-2) is 0.01 moles to 0.40 moles; and the content of the silane monomer (b-3) is 0.40 moles to 0.98 moles.

In one embodiment of the present invention, for the photosensitive polysiloxane composition, relative to the content of polysiloxane (B) as 100 parts by weight, the content of the nitrogen-containing heterocyclic compound (A) is 0.005 parts by weight to 40 parts by weight; the content of o-naphthoquinone diazide sulfonate (C) is 1 part by weight to 50 parts by weight; and the content of the solvent (D) is 100 parts by weight to 1000 parts by weight.

In one embodiment of the present invention, for the photosensitive polysiloxane composition, the silane monomer (b-3) further comprises a silane monomer (b-3-1) of the formula (8-1):

Si(OR⁸²)₄ formula (8-1),
wherein, in the formula (8-1), R⁸² represents hydrogen, an alkyl group of 1-6 carbon atoms, an acyl group of 1-6 carbon atoms, an aryl group of 6-15 carbon atoms, and for the plurality of R⁸², R⁸² may be the same or different.

In one embodiment of the present invention, for the photosensitive polysiloxane composition, relative to the total content of the silane monomers in the mixture as 1.0 mole, the content of the silane monomer (b-3-1) is 0.10 moles to 0.60 moles.

The present invention also provides a protective film containing the above-described photosensitive polysiloxane composition.

The present invention provides a device having a protective film thereon, and the protective film is formed from the above-described photosensitive polysiloxane composition.

The present invention also provides a film forming method comprising forming a film on substrate by applying the above-described photosensitive polysiloxane composition on the substrate.

In one embodiment of the present invention, the afore-mentioned protective film is a planarization film or interlayer insulation film for substrates of liquid crystal displays or organic electro-luminescence displays, or a protective film for optical waveguide core materials or coating materials.

In conclusion, the photosensitive polysiloxane composition of the present invention, formed as a protective film, can effectively improve the adhesion between the protective film formed by the conventional photosensitive composition and the device to be protected and the protective film has a satisfactory taper angle there-between.

In order to make the above and other features and advantages of the present invention more comprehensible, embodiments accompanied with figures are described in detail below.

### DESCRIPTION OF THE EMBODIMENTS

### Photosensitive Polysiloxane Composition Preparation

The present invention provides a photosensitive polysiloxane composition comprising a nitrogen-containing heterocyclic compound (A), polysiloxane (B), o-naphthoquinone diazide sulfonate (C), and a solvent (D). In addition, if necessary, the photosensitive polysiloxane composition may further include an additive (E). The following contexts will detail the components used in the photosensitive polysiloxane composition of the present invention.

### Nitrogen-Containing Heterocyclic Compound (A)

The nitrogen-containing heterocyclic compound (A) is selected from the group consisting of the compounds represented by formulas (1) to (4). Specifically, the compound represented by formula (1) to formula (4) are as follows:

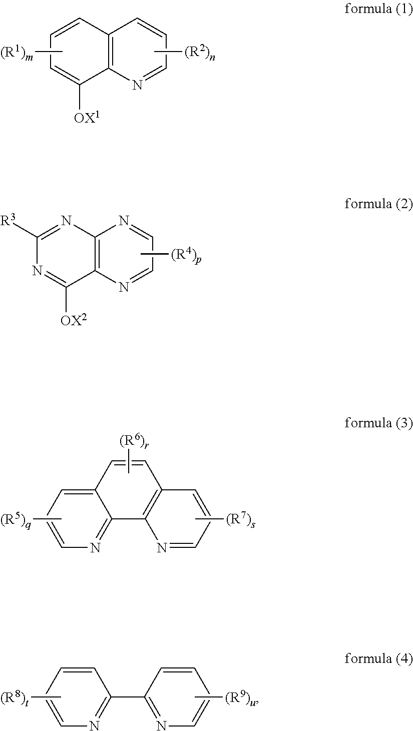

wherein in the formulas (1) to (4), X¹ and X² each independently represents hydrogen, an acyl or an alkyl group; R¹ to R⁹ each independently represents hydrogen, a hydroxyl group, a carboxyl group (—COOH), a sulfo group (—SO₃H), an alkyl group, an amino group, halogen or a mercapto group (—SH); m, n, q and s each independently represents an integer selected from 0, 1, 2 and 3; p and r each independently represents an integer selected from 0, 1 and 2; t and u each independently represents an integer selected from 0, 1, 2, 3 and 4.

In the formulas (1) to (4), X¹ and X² each independently represents hydrogen, an acyl or an alkyl group. Specifically, X¹ and X² each is preferably an acyl group of 2-4 carbon atoms (such as acetyl group, propionyl group or butyryl group) or an alkyl group of 1-3 carbon atoms (such as methyl, ethyl, i-propyl or n-propyl).

In the formulas (1) to (4), R¹ to R⁹ each independently represents hydrogen, a hydroxyl group, a carboxyl group, a sulfo group, an alkyl group, an amino group, halogen or a mercapto group. Specifically, when R¹ to R⁹ is an alkyl group, R¹ to R⁹ each preferably is an alkyl group of 1-3 carbon atoms (e.g. methyl, ethyl, isopropyl or n-propyl). When R¹ to R⁹ is halogen, R¹ to R⁹ each preferably is chlorine, bromine or iodine. When R¹ to R⁹ is an amino group, the hydrogen(s) of the amino group may be substituted by one or two alkyl groups of 1-3 carbon atoms (e.g. methyl, ethyl, isopropyl or n-propyl). In addition, R¹ to R⁹ each may be an alkyl group of 1-3 carbon atoms and having the amine group(s) (e.g. amino methyl, amino ethyl, amino isopropyl or amine n-propyl).

It is noted that in the formulas (1) to (4), when m, n, p, q, r or s is greater than or equal to 2, R¹, R², R⁴, R⁵, R⁶ and R⁷ may be the same or different groups.

The nitrogen-containing heterocyclic compound (A) may be, for example, 6-methyl-8-hydroxyquinoline, 6-ethyl-8-hydroxyquinoline, 5-methyl-8-hydroxyquinoline, 8-hydroxyquinoline, 8-acetyloxy quinoline, 4-hydroxypteridine, 2,4-dihydroxypteridine, 4-hydroxypteridine-2-sulfonic acid, 2-ethyl-4-hydroxypteridine, 2-methyl-4-hydroxypteridine, 2-amino-6,7-dimethyl-4-hydroxypteridine, 1,10-phenanthroline, 5,6-dimethyl-1,10-phenanthroline, 3,8-dimethyl-1,10-phenanthroline, 3,8-dihydroxy-1,10-phenanthroline, 5-carboxy-1,10-phenanthroline, 5,6-dihydroxy-1,10-phenanthroline, 1,10-phenanthroline-5-sulfonic acid, 4,4′-dimethyl-2,2′-bipyridyl, 2,2′-bipyridyl, 2,2′-bipyridyl-5-carboxylic acid, 5,5′-dichloro-2,2′-bipyridyl, 3,3′-dihydroxy-2,2′-bipyridyl, 3,3′-dimercapto-2,2′-bipyridyl or the combinations thereof.

Concerning the adhesion property, based on 100 parts by weight of polysiloxane (B), the content of the nitrogen-containing heterocyclic compound (A) is 0.005 parts by weight to 40 parts by weight; preferably 0.01 parts by weight to 3.5 parts by weight; and more preferably 0.05 parts by weight to 3 parts by weight.

### Polysiloxane (B)

The type of polysiloxane (B) is not particularly limited, as long as the purpose of the present invention can be fulfilled. Polysiloxane (B) is preferably obtained by polymerization (i.e. hydrolysis and partial condensation) using silane monomer(s), siloxane prepolymer(s) or the combination of silane monomer(s) and siloxane prepolymer(s).

The polysiloxane (B) is formed by polycondensation of a mixture, wherein the mixture includes a silane monomer (b-1), a silane monomer (b-2), and a silane monomer (b-3). Each component of the mixture and the reaction steps and conditions of the polycondensation are further described below.

Silane Monomer (b-1)

The silane monomer (b-1) is a compound represented by the formula (5):

Si(R¹⁰)_{w}(OR¹¹)_{4-w} formula (5),

wherein, in the formula (5), R¹⁰ represents hydrogen, an alkyl group of 1-10 carbon atoms, an alkenyl group of 2-10 carbon atoms, an aryl group of 6-15 carbon atoms, an alkyl group containing an acid anhydride group, an alkyl group containing an epoxy group, an alkoxy group containing an epoxy group, and R¹⁰ comprises at least one alkyl group containing an acid anhydride group, and for more than one R¹⁰, R¹⁰ may be the same or different; R¹¹ represents hydrogen, an alkyl group of 1-6 carbon atoms, an acyl group of 1-6 carbon atoms, an aryl group of 6-15 carbon atoms, and for more than one R¹¹, R¹¹ may be the same or different; w represents an integer selected from 1, 2 and 3.

In details, when R¹⁰ in formula (5) represents an alkyl group of 1-10 carbon atoms, more specifically, R¹⁰ is, for example methyl, ethyl, n-propyl, isopropyl, n-butyl group, tertiary butyl, n-hexyl or n-decyl. Also, R¹⁰ may also be an alkyl group with other substituted group(s), specifically, R¹⁰ is, for example trifluoromethyl, 3,3,3-trifluoro-propyl, 3-aminopropyl, 3-mercaptopropyl or 3-isocyanatepropyl.

In details, when R¹⁰ in formula (5) represents an alkenyl group of 2-10 carbon atoms, specifically, R¹⁰ is, for example vinyl. Also, R¹⁰ may also be an alkenyl group with other substituent group(s), specifically, R¹⁰ is, for example 3-acryloyl-propyl or 3-methyl-acryloyloxy-propyl.

More specifically, when R¹⁰ in formula (5) represents an aryl group of 6-15 carbon atoms, R¹⁰ is, for example phenyl, tolyl, or naphthyl. Also, R¹⁰ may also be an aryl group having other substituents in the aromatic group, and specifically, R¹⁰ is, for example, p-hydroxyphenyl, 1-(p-hydroxyphenyl)ethyl, 2-(p-hydroxyphenyl)ethyl or 4-hydroxy-5-(p-hydroxyphenylcarbonyloxy) pentyl.

Furthermore, when R¹⁰ in formula (5) represents an alkyl group containing an acid anhydride group, wherein the alkyl group is preferably an alkyl group of 1-10 carbon atoms. Specifically, the alkyl group containing an acid anhydride group is, for example, represented by formulas (5-1) to (5-3) as shown below. It is noted that the acid anhydride group is formed by intramolecular dehydration of dicarboxylic acid(s), and the dicarboxylic acid may be succinic acid or glutaric acid, for example.

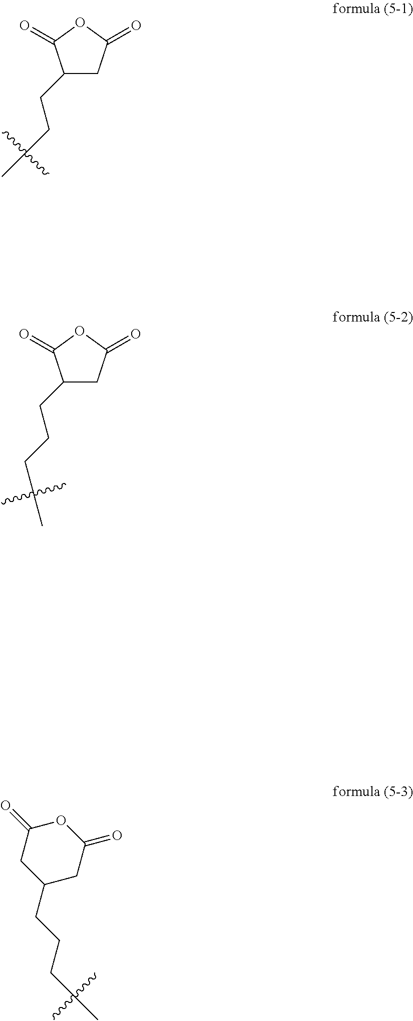 [SMILES: *CCC1CC(=O)OC1=O ; *CCCC1CC(=O)OC1=O ; *CCCC1CC(=O)OC(=O)C1]

Furthermore, when R¹⁰ in formula (5) represents an alkyl group containing an epoxy group, wherein the alkyl group is preferably an alkyl group of 1-10 carbon atoms. Specifically, the alkyl group containing an epoxy group is, for example, oxetanylpentyl or 2-(3,4-epoxycyclohexyl)ethyl. It is noted that the epoxy group is a group formed by intramolecular dehydration of diol(s), and the diol is, for example, propylene glycol, butanediol, pentanediol.

When R¹⁰ in formula (5) represents an alkoxy group containing an epoxy group, wherein the alkoxy group is preferably an alkoxy group of 1-10 carbon atoms. Specifically, the alkoxy group containing an epoxy group, for example, is glycidoxypropyl or 2-oxetanylbutoxy.

Further, when R¹¹ in formula (5) represents an alkyl group of 1-6 carbon atoms, specifically, R¹¹ is, for example, methyl, ethyl, n-propyl, isopropyl or n-butyl. When R¹¹ in formula (5) represents an acyl group of 1-6 carbon atoms, more specifically, R¹¹ is, for example, acetyl. More specifically, when R¹¹ in formula (5) represents an aryl group of 6-15 carbon atoms, R¹¹ is, for example, phenyl.

In formula (5), w is an integer selected from 1, 2 and 3. When w represents 2 or 3, a plurality of R¹⁰ may be the same or different; when w represents 1 or 2, a plurality of R¹¹ may be the same or different.

In the formula (5), when w=1, which means that silane monomer is trifunctional silane monomer (i.e., silane monomer with three hydrolyzable groups); when w=2, which means that silane monomer is bifunctional silane monomer (i.e., silane monomer having two hydrolyzable groups; when w=3, which means that silane monomer is monofunctional silane monomer (i.e. silane monomer having one hydrolyzable group). It is noted that such hydrolyzable group is defined as the group joined the hydrolysis reaction and bonded with the silicon. For example, a hydrolyzable group may be an alkoxy group, an acyloxy group, or a phenoxy group, for example.

Specific examples of formula (5) are: (1) trifunctional silane monomers: 3-triphenoxysilyl propyl succinic anhydride, the commercially available products from Shin-Etsu Chemical Co., Ltd.: 3-trimethoxysilyl propyl succinic anhydride (trade name: X-12-967), the commercially available products from WACKER Company: 3-(triethoxysilyl) propyl succinic anhydride (trade name: GF-20), 3-(trimethoxysilyl) propyl glutaric anhydride (TMSG), 3-(triethoxysilyl) propyl glutaric anhydride, or 3-(triphenoxysilyl) propyl glutaric anhydride; (2) bifunctional silane monomers: di-(n-butoxysilyl)di(propyl succinic anhydride) or (dimethoxysilyl)di(ethyl succinic anhydride); or (3) monofunctional silane monomers: phenoxysilyltripropyl succinic anhydride or methoxysilyldiethyl succinic anhydride. These silane monomers may be used singly or in combination of plural types.

Concerning the adhesion property and the taper angle, based on 1 mole of the total silane monomers in the mixture, the content of the silane monomer (b-1) is 0.01 moles to 0.20 moles; preferably 0.02 moles to 0.19 moles; and more preferably 0.03 moles to 0.18 moles.

Silane Monomer (b-2)

The silane monomer (b-2) is a compound represented by the formula (7):

Si(R⁷⁰)ᵥ(OR⁷¹)₄₋ᵥ formula (7),

wherein, in the formula (7), R⁷⁰ represents hydrogen, an alkyl group of 1-10 carbon atoms, an alkenyl group of 2-10 carbon atoms, an aryl group of 6-15 carbon atoms, an alkyl group containing an acid anhydride group, an alkyl group containing an epoxy group, an alkoxy group containing an epoxy group, and R⁷¹ comprises at least one alkyl group containing an epoxy group or an alkoxy group containing an epoxy group, and for more than one R⁷⁰, R⁷⁰ may be the same or different; R⁷¹ represents hydrogen, an alkyl group of 1-6 carbon atoms, an acyl group of 1-6 carbon atoms, an aryl group of 6-15 carbon atoms, and for more than one R⁷¹, R⁷¹ may be the same or different; v represents an integer selected from 1, 2 and 3.

Specific examples of R⁷⁰ and R⁷¹ are the same as R¹⁰ and R¹¹; and specific examples of formula (7) are: (1) trifunctional silane monomers: 3-acryoyloxypropyltrimethoxysilane, 3-methylacryloyloxypropyltrimethoxysilane (MPTMS), 3-methylacryloyloxypropyltriethoxysilane, 3-glycidoxypropyltrimethoxysilane, 3-glycidoxypropyltriethoxysilane, 2-(3,4-epoxycyclohexyl)ethyltrimethoxysilane, 2-oxetanylbutoxypropyltriphenoxysilane, the commercially available products from Toagosei Company: 2-oxetanylbutoxypropyltrimethoxysilane (trade name: TMSOX-D), 2-oxetanylbutoxypropyltriethoxysilane (trade name: TESOX-D); (2) bifunctional silane monomers: di(3-oxetanylpentyl)dimethoxy silane; or (3) monofunctional silane monomers: 3-glycidoxypropyldimethylmethoxysilane, 3-glycidoxypropyldimethylethoxysilane, di(2-oxetanylbutoxypentyl)-2-oxetanylpentylethoxysilane, tri(2-oxetanylpentyl)methoxy silane. These silane monomers may be used singly or in combination of plural types.

Concerning the adhesion property and the taper angle, based on 1 mole of the total silane monomers in the mixture, the content of the silane monomer (b-2) is 0.01 moles to 0.40 moles; preferably 0.02 moles to 0.38 moles; and more preferably 0.05 moles to 0.35 moles.

Silane Monomer (b-3)

The silane monomer (b-3) is selected from the group consisting of a silane monomer represented by formula (8), a siloxane prepolymer, and a silica particle.

The silane monomer represented by formula (8) is as shown below.

Si(R⁸⁰)_{f}(OR⁸¹)_{4-f} formula (8),

wherein, in the formula (8), R⁸⁰ represents hydrogen, an alkyl group of 1-10 carbon atoms, an alkenyl group of 2-10 carbon atoms, an aryl group of 6-15 carbon atoms, and for more than one R⁸⁰, R⁸⁰ may be the same or different; R⁸¹ represents hydrogen, an alkyl group of 1-6 carbon atoms, an acyl group of 1-6 carbon atoms, an aryl group of 6-15 carbon atoms, and for more than one R⁸¹, R⁸¹ may be the same or different; f represents an integer selected from 0, 1, 2 and 3.

In details, when R⁸⁰ in formula (8) represents an alkyl group of 1-10 carbon atoms, more specifically, R⁸⁰ is, for example methyl, ethyl, n-propyl, isopropyl, n-butyl group, tertiary butyl, n-hexyl or n-decyl. Also, R⁸⁰ may also be an alkyl group with other substituted group(s), specifically, R⁸⁰ is, for example trifluoromethyl, 3,3,3-trifluoro-propyl, 3-aminopropyl, 3-mercaptopropyl or 3-isocyanatepropyl.

In details, when R⁸⁰ in formula (8) represents an alkenyl group of 2-10 carbon atoms, specifically, R⁸⁰ is, for example vinyl. Also, R⁸⁰ may also be an alkenyl group with other substituent group(s), specifically, R⁸⁰ is, for example 3-acryloyl-propyl or 3-methyl-acryloyloxy-propyl.

More specifically, when R⁸⁰ in formula (8) represents an aryl group of 6-15 carbon atoms, R⁸⁰ is, for example phenyl, tolyl, or naphthyl. Also, R⁸⁰ may also be an aryl group having other substituents in the aromatic group, and specifically, R¹⁰ is, for example, p-hydroxyphenyl, 1-(p-hydroxyphenyl)ethyl, 2-(p-hydroxyphenyl)ethyl or 4-hydroxy-5-(p-hydroxyphenylcarbonyloxy) pentyl.

Further, when R⁸¹ in formula (8) represents an alkyl group of 1-6 carbon atoms, specifically, R⁸¹ is, for example, methyl, ethyl, n-propyl, isopropyl or n-butyl. When R⁸¹ in formula (8) represents an acyl group of 1-6 carbon atoms, more specifically, R⁸¹ is, for example, acetyl. More specifically, when R⁸¹ in formula (8) represents an aryl group of 6-15 carbon atoms, R⁸¹ is, for example, phenyl.

In formula (8), f is an integer selected from 0, 1, 2 and 3. When w represents 2 or 3, a plurality of R⁸⁰ may be the same or different; when f represents 1 or 2, a plurality of R⁸¹ may be the same or different.

In the formula (8), when f=0, which means that silane monomer is tetrafunctional silane monomer (i.e., silane monomer having four hydrolyzable groups); when f=1, which means that silane monomer is trifunctional silane monomer (i.e., silane monomer with three hydrolyzable groups); when f=2, which means that silane monomer is bifunctional silane monomer (i.e., silane monomer having two hydrolyzable groups; when f=3, which means that silane monomer is monofunctional silane monomer (i.e. silane monomer having one hydrolyzable group). It is noted that such hydrolyzable group is defined as the group joined the hydrolysis reaction and bonded with the silicon. For example, a hydrolyzable group may be an alkoxy group, an acyloxy group, or a phenoxy group, for example.

Specific examples of the silane monomer represented by formula (8) include:

(1) a tetrafunctional silane monomer: tetramethoxysilane, tetraethoxysilane, tetraacetoxysilane, or tetraphenoxy silane;

(2) a trifunctional silane monomer: methyltrimethoxysilane (MTMS), methyltriethoxysilane, methyltriisopropoxysilane, methyltri-n-butoxysilane, ethyltrimethoxysilane, ethyltriethoxysilane, ethyltriisopropoxysilane, ethyltri-n-butoxysilane, n-propyltrimethoxysilane, n-propyltriethoxysilane, n-butyltrimethoxysilane, n-butyltriethoxysilane, n-hexyltrimethoxysilane, n-hexyltriethoxysilane, decyltrimethoxysilane, vinyltrimethoxysilane, vinyltriethoxysilane, 3-acryoyloxypropyltrimethoxysilane, 3-methylacryloyloxypropyltrimethoxysilane (MPTMS), 3-methylacryloyloxypropyltriethoxysilane, phenyltrimethoxysilane (PTMS), phenyltriethoxysilane (PTES), p-hydroxyphenyltrimethoxysilane, 1-(p-hydroxyphenyl)ethyltrimethoxysilane, 2-(p-hydroxyphenyl)ethyltrimethoxysilane, 4-hydroxy-5-(p-hydroxyphenylcarbonyloxy)pentyltrimethoxysilane, trifluoromethyltrimethoxysilane, trifluoromethyltriethoxysilane, 3,3,3-trifluoropropyltrimethoxysilane, 3-aminopropyltrimethoxysilane, 3-aminopropyltriethoxysilane, or 3-mercaptopropyltrimethoxysilane;

(3) a bifunctional silane monomer: dimethyldimethoxysilane (DMDMS), dimethyldiethoxysilane, dimethyldiacetyloxysilane, di-n-butyldimethoxysilane, or diphenyldimethoxysilane; or

(4) a monofunctional silane monomer: trimethylmethoxysilane or tri-n-butylethoxysilane . . . etc. The various silane monomers can be used alone or in multiple combinations.

Based on 1 mole of the total silane monomers in the mixture, the content of the silane monomer (b-3) is 0.40 moles to 0.98 moles; preferably 0.43 moles to 0.96 moles; and more preferably 0.47 moles to 0.92 moles.

Concerning the taper angle, the silane monomer (b-3) is preferably the silane monomer (b-3-1) represented by formula (8-1):

Si(OR⁸²)₄ formula (8-1),

wherein, in the formula (8-1), R⁸² represents hydrogen, an alkyl group of 1-6 carbon atoms, an acyl group of 1-6 carbon atoms, an aryl group of 6-15 carbon atoms, and for more than one R⁸², R⁸² may be the same or different.

In detail, when R⁸² in formula (8-1) represents an alkyl group of 1-6 carbon atoms, specifically, R⁸² is, for example, methyl, ethyl, n-propyl, isopropyl or n-butyl. When R⁸² in formula (8-1) represents an acyl group of 1-6 carbon atoms, more specifically, R⁸² is, for example, acetyl. More specifically, when R⁸² in formula (8-1) represents an aryl group of 6-15 carbon atoms, R⁸² is, for example, phenyl.

Specific examples of the silane monomer represented by formula (8-1) include tetrafunctional silane monomers: tetramethoxysilane, tetraethoxysilane, tetraacetoxysilane, or tetraphenoxy silane. The various silane monomers can be used alone or in multiple combinations.

Based on 1 mole of the total silane monomers in the mixture, the content of the silicon-containing compound (b-3-1) is 0.10 moles to 0.60 moles; preferably 0.15 moles to 0.60 moles; and more preferably 0.15 moles to 0.55 moles.

The polysiloxane (B) preferably includes a polysiloxane prepolymer represented by the formula (5-4):

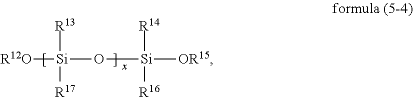

wherein, in the formula (5-4), R¹³, R¹⁴, R¹⁶ and R¹⁷ each independently represents hydrogen, an alkyl group of 1-10 carbon atoms, an alkenyl group of 2-6 carbon atoms, an aryl group of 6-15 carbon atoms. R¹² and R¹⁵ each independently represents hydrogen, an alkyl group of 1-6 carbon atoms, an acyl group of 1-6 carbon atoms, an aryl group of 6-15 carbon atoms. x represents an integer selected of from 1 to 1000.

In the formula (5-4), when R¹³, R¹⁴, R¹⁶ and R¹⁷ each independently represents an alkyl group of 1-10 carbon atoms, for example, R¹³, R¹⁴, R¹⁶ and R¹⁷ each independently is methyl, ethyl or n-propyl. In the formula (5-4), when R¹³, R¹⁴, R¹⁶ and R¹⁷ each independently represents an alkenyl group of 2-6 carbon atoms, for example, R¹³, R¹⁴, R¹⁶ and R¹⁷ each independently is vinyl, 3-acryloyl-propyl or 3-methyl-acryloyloxy-propy. In the formula (5-4), when R¹³, R¹⁴, R¹⁶ and R¹⁷ each independently represents an aryl group of 6-15 carbon atoms, for example, R¹³, R¹⁴, R¹⁶ and R¹⁷ each independently is phenyl, tolyl, naphthyl and so on. It is noted that any one of the above alkyl group, alkenyl group and aryl group may optionally have a substituent.

In the formula (5-4), when R¹² and R¹⁵ each independently represents an alkyl group of 1-6 carbon atoms, for example, R¹² and R¹⁵ each independently is methyl, ethyl, n-propyl, isopropyl or n-butyl. In the formula (5-4), when R¹² and R¹⁵ each independently represents an acyl group of 1-6 carbon atoms, for example, R¹² and R¹⁵ each independently is acetyl. In the formula (5-4), when R¹² and R¹⁵ each independently represents an aryl group of 6-15 carbon atoms, for example, R¹² and R¹⁵ each independently is phenyl. It is noted that any one of the above alkyl group, acyl group and aryl group may have a substituent.

In the formula (5-4), x is an integer selected from 1 to 1000, x preferably is an integer selected from 3 to 300, and x more preferably is an integer selected from 5 to 200. When x is an integer from 2 to 1000, R¹³ may be the same or different groups, and R¹⁷ may be the same or different groups.

The polysiloxane prepolymer in formula (5-4) may be, for example, 1,1,3,3-tetramethyl-1,3-dimethoxy disiloxane, 1,1,3,3-tetramethyl-1,3-diethoxy disiloxane, 1,1,3,3-tetraethyl-1,3-diethoxy disiloxane or the commercially available products of silanol terminated polydimethylsiloxane by Gelest Company (trade names such as DM-S12 (molecular weight of 400 to 700), DMS-S15 (molecular weight of 1500 to 2000), DMS-S21 (molecular weight 4200), DMS-S27 (molecular weight 18000), DMS-S31 (molecular weight 26000), DMS-S32 (molecular weight 36000), DMS-S33 (molecular weight 43500), DMS-S35 (molecular weight 49000), DMS-S38 (MW 58000) DMS-S42 (molecular weight 77000) or PDS-9931 (MW 1000-1400)). The polysiloxane prepolymer represented by formula (5-4) may be used singly or in combination of plural types.

It is noted that the silane monomer may be used in combination with the polysiloxane prepolymer, and the mixing ratio thereof is not particularly limited. Preferably, the molar ratios of silicon atoms in the silane monomer and the polysiloxane prepolymer are from 100:0.01 to 50:50.

In addition, the polysiloxane (B) may be prepared through copolymerization of the silane monomer and/or the polysiloxane prepolymer, or in combination with silicon dioxide particles.

The average particle diameter of silicon dioxide particles is not particularly limited. The average particle diameter ranges from 2 nm to 250 nm, preferably from 5 nm to 200 nm, and more preferably from 10 nm to 100 nm.

Silicon dioxide particles are, for example, commercially available products manufactured by Jgc Catalysts & Chemicals Co., Ltd. (trade names: Oscar 1132 (particle diameter of 12 nm; dispersing agent is methanol), OSCAR 1332 (particle diameter of 12 nm; dispersant n-propanol), OSCAR 105 (particle size 60 nm; dispersant γ-butyrolactone), OSCAR 106 (particle diameter of 120 nm; dispersant diacetone alcohol), etc.); commercially available products by Fuso Chemical Co. (trade names: Quartron PL-1-IPA (particle diameter of 13 nm; dispersant isobutyl ketone), Quartron PL-1-TOL (particle diameter of 13 nm; dispersant toluene), Quartron PL-2L-PGME (18 nm particle size; diacetone alcohol propylene glycol monomethyl ether) or Quartron PL-2L-MEK (particle size 18 nm; dispersant methyl ethyl ketone); or commercially available products manufactured by Nissan Chemical Company (trade names, such as IPA-ST (particle diameter 12 nm; dispersant isopropanol), EG-ST (particle diameter of 12 nm; dispersant ethylene glycol), IPA-ST-L (particle size 45 nm; dispersant isopropanol) or IPA-ST-ZL (particle diameter of 100 nm; dispersant isopropyl alcohol). The silicon dioxide particles may be used singly or in combination of plural types.

The silicon dioxide particles may be used in combination with silane monomer(s) and/or polysiloxane prepolymer(s) and the mixing ratio is not particularly limited. The molar ratio of silicon atoms in the silicon dioxide particles and polysiloxane prepolymer is preferably 1%-50%.

In general, the polymerization reaction (i.e. hydrolysis and condensation) of silane monomer, polysiloxane prepolymer and/or silicon dioxide particles is based on the following steps: solvents, water and optionally catalyst were added in the mixture of silane monomer, polysiloxane prepolymer and/or silicon dioxide particles; heated under 50° C.-150° C. and stirred for 0.5-120 hours, and the byproducts (alcohols, water, etc.) were removed by distillation.

The solvent used in the above polymerization reaction is not particularly limited, and the solvent may be the same or different from the solvent (D) included in the photosensitive polysiloxane composition of the present invention. Relative to the total amount of silane monomer, polysiloxane prepolymer and/or silicon dioxide particles being 100 grams, the content of the solvent is preferably 15-1200 g; preferably 20-1100 g; and more preferably 30-1000 g.

Relative to the hydrolyzable groups of the silane monomer, polysiloxane prepolymer and/or silicon dioxide particles being 1 mole, the amount of water used in the above polymerization reaction (i.e., water used in hydrolysis) is 0.5 moles to 2 moles.

The catalyst used in the above polymerization reaction is not particularly limited, and is preferably selected from the group consisting of an acidic catalyst or a basic catalyst. The acidic catalyst may be, for example, hydrochloric acid, nitric acid, sulfuric acid, hydrofluoric acid, oxalic acid, phosphoric acid, acetic acid, trifluoroacetic acid, formic acid, polybasic carboxylic acid or an anhydride thereof, or ion exchange resins. The basic catalyst may be, for example, diethylamine, triethylamine, tripropylamine, tributylamine, tripentylamine, trihexylamine, triheptylamine, trioctylamine, diethanolamine, triethanolamine, sodium hydroxide, potassium hydroxide, the amine group-containing silane having an alkoxy group or ion exchange resins and the like.

Relative to the total amount of the silane monomer, polysiloxane prepolymer and/or silica particles being 100 grams, the content of the catalyst used in the above polymerization reaction preferably ranges from 0.005 g to 15 g; more preferably 0.01 g to 12 g; and most preferably from 0.05 g to 10 g.

Concerning stability, the polysiloxane (B) preferably excludes byproducts (such as alcohols or water) and the catalyst. Accordingly, the reaction mixture may be optionally purified after the polymerization reaction to obtain the purified polysiloxane (B). The purification method is not particularly limited. A hydrophobic solvent is preferably used for the dilution of the reaction mixture. Subsequently, the hydrophobic solvent and the reaction mixture were transferred to a separation funnel, and the organic layer was then washed with water several times and concentrated by rotary evaporator to remove the alcohol or water. In addition, ion exchange resins may be used to remove the catalyst.

### O-Naphthoquinone Diazide Sulfonate (C)

The types of o-naphthoquinone diazide sulfonate (C) are not particularly limited, and the commonly used o-naphthoquinone diazide sulfonate may be used. Such o-naphthoquinone diazide sulfonate (C) may be completely esterified or partially esterified ester-based compound(s).

O-naphthoquinone diazide sulfonate (C) is preferred prepared by reacting the hydroxy compound(s) with o-naphthoquinone diazide sulfonic acid or salts thereof. O-naphthoquinone diazide sulfonate (C) is more preferably prepared by the reaction of o-naphthoquinone diazide sulfonic acid or salts thereof with polyhydric hydroxy compound.

O-naphthoquinone diazide sulfonic acid may be, for example, o-naphthoquinone diazide-4-sulfonic acid, o-naphthoquinone diazide-5-sulfonic acid or o-naphthoquinone diazide-6-sulfonic acid. In addition, the o-naphthoquinone diazide sulfonic acid salts may be, for example, o-naphthoquinone diazonaphthoquinone sulfonyl halides.

The hydroxy compound may be, for example: (1) hydroxybenzophenone-based compounds, such as, 2,3,4-trihydroxy-benzophenone, 2,4,4′-trihydroxy-benzophenone, 2,4,6-trihydroxy-benzophenone, 2,3,4,4′-tetrahydroxy benzophenone, 2,4,2′,4′-tetrahydroxy benzophenone, 2,4,6,3′,4′-pentahydroxy-benzophenone, 2,3,4,2′,4′-pentahydroxy-benzophenone, 2,3,4,2′,5′-pentahydroxy-benzophenone, 2,4,5,3′,5′-pentahydroxy-benzophenone or 2,3,4,3′,4′,5′-hexahydroxy-benzophenone.

(2) hydroxyaryl-based compounds, for example, as shown by the formula (6-1) hydroxy aryl compound category:

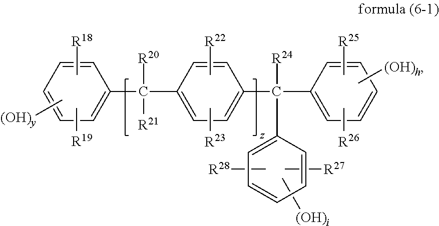

wherein, in the formula (6-1), R¹⁸ and R¹⁹ each independently represents hydrogen, halogen or an alkyl group of 1-6 carbon atoms; R²⁰, R²¹, R²⁴ each independently represents hydrogen or an alkyl group of 1-6 carbon atoms; R²², R²³, R²⁵, R²⁶, R²⁷ and R²⁸ each independently represents hydrogen, halogen, an alkyl group of 1-6 carbon atoms, an alkoxy group of 1-6 carbon atoms, an alkenyl group of 1-6 carbon atoms or a cycloalkyl group of 1-6 carbon atoms; h, i and y each independently represents an integer selected from 1 to 3; z represents 0 or 1.

Specifically, hydroxyaryl-based compounds as shown in formula (6-1) may be, for example, tris(4-hydroxyphenyl) methane, bis(4-hydroxy-3,5-dimethyl-phenyl)-4-hydroxyphenyl methane, bis(4-hydroxy-3,5-dimethyl-phenyl)-3-hydroxyphenyl methane, bis(4-hydroxy-3,5-dimethyl-phenyl)-2-hydroxyphenyl methane, bis(4-hydroxy-2,5-dimethylphenyl)-4-hydroxyphenyl methane, bis(4-hydroxy-2,5-dimethylphenyl)-3-hydroxyphenyl methane, bis(4-hydroxy-2,5-dimethylphenyl)-2-hydroxyphenyl methane, bis(4-hydroxy-3,5-dimethylphenyl)-3,4-bis(hydroxyphenyl) methane bis(4-hydroxy-2,5-dimethylphenyl)-3,4-dihydroxyphenyl methane, bis(4-hydroxy-3,5-dimethylphenyl)-2,4-hydroxyphenyl methane, bis(4-hydroxy-2,5-dimethylphenyl)-2,4-dihydroxyphenyl methane, bis(4-hydroxyphenyl)-3-methoxy-4-hydroxyphenyl methane, bis(3-cyclohexyl-4-hydroxyphenyl)-3-hydroxyphenyl methane, bis(3-cyclohexyl-4-hydroxyphenyl)-2-hydroxyphenyl methane, bis(3-cyclohexyl-4-hydroxyphenyl)-4-hydroxyphenyl methane, bis(3-cyclohexyl-4-hydroxy-6-methyl-phenyl)-2-hydroxyphenyl methane, bis(3-cyclohexyl-4-hydroxy-6-methyl-phenyl)-3-hydroxyphenyl methane, bis(3-cyclohexyl-4-hydroxy-6-methylphenyl)-4-hydroxyphenyl methane, bis(3-cyclohexyl-4-hydroxy-6-methyl-phenyl)-3,4-dihydroxyphenyl methane, bis(3-cyclohexyl-6-hydroxyphenyl)-3-hydroxyphenyl methane, bis(3-cyclohexyl-6-hydroxyphenyl)-4-hydroxyphenyl methane, bis(3-cyclohexyl-6-hydroxyphenyl)-2-hydroxyphenyl methane, bis(3-cyclohexyl-6-hydroxy-4-methylphenyl)-2-hydroxyphenyl methane, bis(3-cyclohexyl-6-hydroxy-4-methylphenyl)-4-hydroxyphenyl methane, bis(3-cyclohexyl-6-hydroxy-4-methyl-phenyl)-3,4-dihydroxyphenyl methane, 1-[1-(4-hydroxyphenyl)isopropyl]-4-[1,1-bis(4-hydroxyphenyl)ethyl]benzene or 1-[1-(3-methyl-4-hydroxyphenyl)isopropyl]-4-[1,1-bis(3-methyl-4-hydroxyphenyl)ethyl]benzene.

(3) (hydroxyphenyl) hydrocarbon compounds may be, for example, (hydroxyphenyl) hydrocarbon compounds represented by the formula (6-2) as shown:

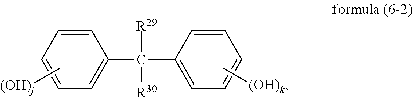

wherein in formula (6-2), R²⁹ and R³⁰ each independently represents hydrogen or an alkyl group of 1-6 carbon atoms; j and k each independently represents an integer selected from 1 to 3.

Specifically, (hydroxyphenyl)-hydrocarbon compounds as shown in the formula (6-2) may be, such as, 2-(2,3,4-trihydroxyphenyl)-2-(2′,3′,4′-trihydroxyphenyl) propane, 2-(2,4-dihydroxyphenyl)-2-(2′,4′-dihydroxyphenyl) propane, 2-(4-hydroxyphenyl)-2-(4′-hydroxyphenyl) propane, bis(2,3,4-trihydroxyphenyl) methane or bis(2,4-dihydroxyphenyl) methane and the like.

(4) other aromatic hydroxyl compounds, such as phenol, p-methoxyphenol, dimethylphenol, hydroquinone, bisphenol A, naphthol, catechol, 1,23-pyrogallol methyl ether, 1,2,3-pyrogallol-1,3-dimethyl ether, 3,4,5-trihydroxy benzoic acid, or partially esterified or etherified 3,4,5-trihydroxy benzoic acid.

The hydroxy compound is preferably 1-[1-(4-hydroxyphenyl) isopropyl]-4-[1,1-bis(4-hydroxyphenyl)ethyl]benzene, 2,3,4-trihydroxy-benzophenone, 2,3,4,4′-tetrahydroxy benzophenone, or a combination thereof. The hydroxy compounds may be used singly or in combination of plural types.

The reaction of o-naphthoquinone diazide sulfonic acid or the salts thereof with the hydroxy compound(s) is usually performed in organic solvents, such as dioxane, N-pyrrolidone, acetamides and etc. Further, the reaction is preferably performed in alkaline condensing agents, such as triethanolamine, alkali metal carbonates or alkali metal bicarbonates.

The degree of esterification of o-naphthoquinone diazide sulfonate (C) is preferably more than 50%. That is, to the total amount of the hydroxyl groups in the hydroxy compound as 100 mol %, 50 mole % or more hydroxyl groups in the hydroxy compound react with o-naphthoquinone diazide sulfonic acid or salts thereof in the esterification reaction. The degree of esterification of o-naphthoquinone diazide sulfonate (C) is more preferably 60% or more.

Based on the total amount of polysiloxane (B) of 100 parts by weight, the content of the o-naphthoquinone diazide sulfonate (C) ranges from 1 part by weight to 50 parts by weight; preferably 2 parts by weight to 45 parts by weight; and more preferably 3 parts by weight to 40 parts by weight.

### Solvent (D)

The type of the solvent (D) is not particularly limited. The solvent (D), for example, is a compound containing an alcoholic hydroxy group or a cyclic compound containing a carbonyl group.

The compound containing an alcoholic hydroxy group may be, for example, acetol, 3-hydroxy-3-methyl-2-butanone, 4-hydroxy-3-methyl-2-butanone, 5-hydroxy-2-pentanone, 4-hydroxy-4-methyl-2-pentanone (also known as diacetone alcohol, DAA), ethyl lactate, butyl lactate, propylene glycol monomethyl ether, propylene glycol monoethyl ether (PGEE), propylene glycol monomethyl ether acetate (PGMEA), propylene glycol mono-n-propyl ether, propylene glycol mono-n-butyl ether, propylene glycol mono-t-butyl ether, 3-methoxy-1-butanol, 3-methyl-3-methoxy-1-butanol or a combination thereof. It is noted that the compound containing an alcoholic hydroxy group is preferred diacetone alcohol, ethyl lactate, propylene glycol monoethyl ether, propylene glycol methyl ether acetate or combinations thereof. The compound containing an alcoholic hydroxy group may be used singly or in combination of plural types.

The cyclic compound containing a carbonyl group may be, for example, γ-butyrolactone, γ-valerolactone, δ-valerolactone, propylene carbonate, N-methyl pyrrolidone, cyclohexanone or cycloheptanone. It is noted that the cyclic compound containing a carbonyl group is preferably γ-butyrolactone, N-methyl pyrrolidone, cyclohexanone or the combinations thereof. The cyclic compound containing a carbonyl group may be used singly or in combination of plural types.

The compound containing an alcoholic hydroxy group may be used in combination with the cyclic compound containing a carbonyl group, and the mixing weight ratio of both is not particularly limited. The weight ratio of the compound containing an alcoholic hydroxy group and the cyclic compound containing a carbonyl group ranges preferably from 99/1 to 50/50; more preferably from 95/5 to 60/40. It is noted that the unreacted silanol (Si—OH) groups in polysiloxane (B), when the weight ratio of the compound containing an alcoholic hydroxy group and the cyclic compound containing a carbonyl group is from 99/1 to 50/50 in the solvent (D), are unlikely to produce a condensation reaction and the storage stability is lowered. In addition, since the compound containing an alcoholic hydroxy group and the cyclic compound containing a carbonyl group have good compatibility with o-naphthoquinone diazide sulfonate (C), it is unlikely that the whitening phenomenon occurs in the coating film and the transparency of the protective film can be maintained.

Without lowering the effect of the present invention, other solvents may be included. These other solvents may be, for example: (1) esters: ethyl acetate, ethyl acetate, n-propyl, iso-propyl acetate, acetate, n-butyl acetate, isobutyl acetate, propylene glycol monomethyl ether acetate, 3-methoxy-1-butyl acetate or 3-methyl-3-methoxy-1-butyl acetate, etc.; (2) ketones: methyl isobutyl ketone, diisopropyl ketone, or di-isobutyl ketone, etc.; or (3) ethers: diethyl ether, diisopropyl ether, di-n-butyl ether or diphenyl ether.

Based on the total amount of the polysiloxane (B) being 100 parts by weight, the content of the solvent (D) is preferably 100 parts by weight to 1000 parts by weight; preferably 75 parts by weight to 1000 parts by weight; and more preferably 90 parts by weight to 900 parts by weight.

### Additive (E)

The photosensitive polysiloxane composition of the present invention may optionally further include additives (E). Specifically, the additives (E) may be, for example, sensitizer, adhesion auxiliary agent, surfactants, dissolution promoters, defoamers, or combinations thereof.

The type of the sensitizer is not particularly limited. The sensitizer may use preferably a compound containing a phenolic hydroxyl group, for example:

(1) trisphenol type compound: such as tris(4-hydroxyphenyl) methane, bis(4-hydroxy-3-methylphenyl)-2-hydroxyphenyl methane, bis(4-hydroxy-2,3,5-trimethylphenyl)-2-hydroxyphenyl methane, bis(4-hydroxy-3,5-dimethylphenyl)-4-hydroxyphenyl methane, bis(4-hydroxy-3,5-dimethylphenyl)-3-hydroxyphenyl methane, bis(4-hydroxy-3,5-methyl-phenyl)-2-hydroxyphenyl methane, bis(4-hydroxy-2,5-dimethyl-phenyl)-4-hydroxyphenyl methane, bis(4-hydroxy-2,5-dimethylphenyl)-3-hydroxyphenyl methane, bis(4-hydroxy-2,5-dimethylphenyl)-2-hydroxyphenyl methane, bis(4-hydroxy-3,5-dimethyl-phenyl)-3,4-dihydroxyphenyl methane, bis(4-hydroxy-2,5-dimethylphenyl)-3,4-dihydroxyphenyl methane, bis(4-hydroxy-2,5-dimethylphenyl)-2,4-bis(hydroxyphenyl) methane, bis(4-hydroxy-phenyl)-3-methoxy-4-hydroxyphenyl methane, bis(5-cyclohexyl-4-hydroxy-2-methyl-phenyl)-4-hydroxyphenyl methane, bis(5-cyclohexyl-4-hydroxy-2-methyl-phenyl)-3-hydroxyphenyl methane, bis(5-cyclohexyl-4-hydroxy-2-methyl-phenyl)-2-hydroxyphenyl methane or bis(5-cyclohexyl-4-hydroxy-2-methyl-phenyl)-3,4-dihydroxyphenyl methane, etc.;

(2) bisphenol type compound: such as bis(2,3,4-trihydroxyphenyl) methane, bis(2,4-dihydroxyphenyl) methane, 2,3,4-trihydroxy-phenyl-4′-hydroxyphenyl methane, 2-(2,3,4-trihydroxyphenyl)-2-(2′,3′,4′-trihydroxyphenyl) propane, 2-(2,4-dihydroxyphenyl)-2-(2′,4′-dihydroxyphenyl) propane, 2-(4-hydroxyphenyl)-2-(4′-hydroxyphenyl) propane, 2-(3-fluoro-4-hydroxyphenyl)-2-(3′-fluoro-4′-hydroxyphenyl) propane, 2-(2,4-dihydroxyphenyl)-2-(4′-hydroxyphenyl) propane, 2-(2,3,4-trihydroxyphenyl)-2-(4′-hydroxyphenyl) propane or 2-(2,3,4-trihydroxyphenyl)-2-(4′-hydroxy-3′,5′-dimethylphenyl) propane and the like;

(3) polynuclear branched compounds: such as 1-[1-(4-hydroxyphenyl)isopropyl]-4-[1,1-bis(4-hydroxyphenyl)-ethyl]phenyl or 1-[1-(3-methyl-4-hydroxyphenyl)isopropyl]-4-[1,1-bis(3-methyl-4-hydroxyphenyl)ethyl]benzene and the like;

(4) condensation type phenol compound: such as 1,1-bis(4-hydroxyphenyl)cyclohexane, etc.;

(5) polyhydroxy benzophenones: such as 2,3,4-trihydroxy benzophenone, 2,4,4′-trihydroxy benzophenone, 2,4,6-trihydroxy benzophenone, 2,3,4-trihydroxy-2′-methyl-benzophenone, 2,3,4,4′-tetrahydroxy benzophenone, 2,4,2′,4′-tetrahydroxy benzophenone, 2,4,6,3′,4′-pentahydroxy benzophenone, 2,3,4,2′,4′-pentahydroxy benzophenone, 2,3,4,2′,5′-pentahydroxy benzophenone, 2,4,6,3′,4′,5′-hexahydroxy benzophenone or 2,3,4,3′,4′,5′-hexahydroxy benzophenone; or

(6) the combinations of the above-mentioned compounds containing a phenolic hydroxyl group.

Based on the total amount of the polysiloxane (B) being 100 parts by weight, the content of the sensitizer is 5 parts by weight to 50 parts by weight; preferably 8 parts by weight to 40 parts by weight; and more preferably 10 parts by weight to 35 by weight.

Adhesion auxiliary agents may be, for example, melamine compounds, silane-based compounds and the like. The role of the adhesion auxiliary agent is to increase the adhesion between the device or component to be protected and the protective film that is formed by the photosensitive polysiloxane composition.

Commercially available products of melamine compounds are, for example, manufactured by Mitsui Chemicals, trade names Cymel 300, Cymel-303, etc.; or the products manufactured by Sanwa Chemical, trade names MW-30MH, MW-30, MS-11, MS-001, MX-750 or MX-706.

When using the melamine compound as the adhesion auxiliary agent, based on the total amount of polysiloxane (B) being 100 parts by weight, the content of the melamine compound is from 0 part by weight to 20 parts by weight; preferably from 0.5 parts by weight to 18 wt parts; and more preferably 1.0 part by weight to 15 parts by weight.

Silane-based compounds may be, such as, vinyl trimethoxy silane, vinyl triethoxy silane, 3-acryloyloxy-propyl-trimethoxy silane, vinyl tris(2-methoxyethoxy) silane, N-(2-amino-ethyl)-3-aminopropyl methyl dimethoxy silane, N-(2-aminoethyl)-3-aminopropyl trimethoxy silane, 3-aminopropyl triethoxy silane, 3-glycidoxypropyl trimethoxy silane, 3-glycidoxypropyl dimethyl methoxy-silane, 2-(3,4-epoxy-cyclohexyl)ethyl trimethoxy silane, 3-chloropropyl methyl dimethoxy silane, 3-chloropropyl trimethoxy silane, 3-methacryloxypropyl trimethoxy silane, 3-mercaptopropyl trimethoxy silane or a commercially available product manufactured by Shin-Etsu Chemical Company (trade name of KBM403).

When using a silane-based compound as the adhesion auxiliary agent, based on the total amount of polysiloxane (B) as 100 parts by weight, the content of the silane-based compound is 0 part by weight to 2 parts by weight; preferably 0.05 parts by weight to 1 part by weight; and more preferably 0.1 parts by weight to 0.8 parts by weight.

The surfactants may be, for example, anionic surfactants, cationic surfactants, nonionic surfactants, amphoteric surfactants, polysiloxane-based surfactants, fluorine-based surfactants or a combination thereof.

Examples of the surfactant include (1) polyoxyethylene alkyl ethers: polyoxyethylene lauryl ether, etc.; (2) polyoxyethylene phenyl ethers: polyoxyethylene octyl phenyl ether, polyoxyethylene nonyl phenyl ether, etc.; (3) polyethylene glycol diesters: polyethylene glycol dilaurate, polyethylene glycol distearate, etc.; (4) sorbitan fatty acid esters; and (5) fatty acid modified poly esters; and (6) tertiary amine modified polyurethanes. Commercially available products of surfactant are, for example, KP (manufactured by Shin-Etsu Chemical), SF-8427 (manufactured by Dow Corning Toray Silicone Co., Ltd.), Polyflow (manufactured by Kyoeisha Grease Chemical), F-Top (manufactured by Tochem Products Co., Ltd.), Megaface (manufactured by Dainippon ink chemical industry (DIC)), Fluorade (by Sumitomo 3M Co., Ltd.), Surflon (manufactured by Asahi Glass), SINOPOL E8008 (Sino Japan Chemical Co. Ltd.), F-475 (manufactured by Dainippon ink chemical industry) or combinations thereof.

Based on the total amount of the polysiloxane (B) being 100 parts by weight, the content of the surfactant is 0.5 parts by weight to 50 parts by weight; preferably 1 part by weight to 40 parts by weight; and more preferably 3 to 30 parts by weight.

Examples of defoamers include Surfynol MD-20, Surfynol MD-30, EnviroGem AD01, EnviroGem AE01, EnviroGem AE02, Surfynol DF110D, Surfynol 104E, Surfynol 420, Surfynol DF37, Surfynol DF58, Surfynol DF66, Surfynol DF70 and Surfynol DF210 (manufactured by Air products) and the like. Based on the total amount of the polysiloxane (B) being 100 parts by weight, the content of the defoamer is 1 part by weight to 10 parts by weight; preferably 2 parts by weight to 9 parts by weight; and more preferably 3 parts by weight to 8 parts by weight.

Examples of dissolution promoters include N-hydroxydicarboxylic imide and the compound containing the phenolic hydroxyl group. For example, dissolution promoter is the compound containing the phenolic hydroxyl group used in o-naphthoquinone diazide sulfonate (C). Based on the total amount of polysiloxane (B) being 100 parts by weight, the content of the dissolution promoter is 1 part by weight to 20 parts by weight; preferably 2 parts by weight to 15 parts by weight; and more preferably 3 parts by weight to 10 parts by weight.

The photosensitive polysiloxane composition may be prepared in the following manner: the nitrogen-containing heterocyclic compounds (A), polysiloxane (B), o-naphthoquinone diazide sulfonate (C) and the solvent (D) are placed in a blender and stirred until homogeneously mixed into a solution state. If necessary, additives (E) may be added.

### <Methods for Forming Protective Film and the Device Having the Protective Film Thereon>

The present invention provides a photosensitive polysiloxane composition, which can be used to form a protective film with good adhesion between devices or components to be protected.

The present invention also provides a device with a protective film thereon, including the device and the protective film, and the protective film covering the above-mentioned device. Specifically, the device having the protective film thereon, for example, is a display device, a semiconductor device or an optical waveguide core material or coating material. In addition, the photosensitive polysiloxane composition can also be used to form the planarization film or interlayer insulation film of TFT substrates.

The following descriptions detail the method of forming the protective film, comprising: using a photosensitive polysiloxane composition to form a pre-bake coating film, pattern exposure of the pre-baked coating film, removing the unexposed region of the film by an alkali developer to form the pattern, and performing the post-baking treatment to form a protective film.

### —Form a Pre-Baked Coating Film—

By spin coating, cast coating, or roll coater coating method, the photosensitive polysiloxane composition in the above solution state was coated onto the device to be protected (hereinafter referred to as substrate, to form a coating film.

The above-mentioned substrate may be alkali-free glass, soda lime glass, Pyrex glass, quartz glass, or glasses adhered with the transparent conductive film used in a liquid crystal display device, or the substrate (such as, silicon substrate) used in the photoelectric conversion apparatus (such as a solid-state imaging apparatus).

### —Pattern Exposure—

A mask having a specific pattern is used to perform exposure for the above-mentioned pre-bake coating film. The light used in the exposure process, is preferably ultraviolet (UV) rays (g line, b line, i line, etc.), and the device used to provide UV rays may be an ultra high-pressure mercury lamp or a metal halide lamp.

### —Development—

Unnecessary portions of the above exposed pre-bake coating film are removed by immersing the pre-baked coating film in the developer solution a temperature between 23±2° C. and developing for about 15 seconds to 5 minutes, so as to form a semi-finished product of the protective film with a predetermined pattern on the substrate. The developer may be alkaline compounds, such as, sodium hydroxide, potassium hydroxide, sodium carbonate, sodium hydrogen carbonate, potassium carbonate, potassium bicarbonate, sodium silicate, sodium methylsilicate, aqueous ammonia, ethylamine, diethylamine, dimethyl ethanolamine, tetramethylammonium hydroxide (THAM), tetraethylammonium hydroxide, choline, pyrrole, piperidine, 1,8-diaza-bicyclo-(5,4,0)-7-undecene.

It is noted that if the concentration of the developer is too high, the specific pattern may be damaged or the resolution of the specific pattern may be deteriorated. If the concentration of the developer is too low, poor development may happen, the specific pattern may not be formed or residues of the composition remain in exposed portions. Therefore, the concentration of the developer will affect the formation of a specific pattern of the subsequent photosensitive polysiloxane composition after exposure. The concentration range of the liquid developer is preferably from 0.001 wt % to 10 wt %; more preferably from 0.005 wt % to 5 wt %; further more preferably from 0.01 wt % to 1 wt %. The present embodiment of the present invention employs a developer of 2.38 wt % tetramethylammonium hydroxide. It is noted that even using a lower concentration of the developer, the photosensitive polysiloxane composition of the present invention is capable of forming a fine pattern.

—Baked after Processing—

The substrate (semi-finished product of the protective film with the predetermined pattern on the substrate) was washed with water to remove the unwanted portions of the above-mentioned exposed pre-baked coating film. Then, the compressed air or compressed nitrogen is used to dry up the semi-finished product of the protective film with the predetermined pattern. Finally, the semi-finished product of the protective film with the predetermined pattern was post-baked on a heating plate or oven. The heating temperature was set between 100° C. to 250° C., and the heating time with a hot plate is 1-60 minutes or the heating time with an oven was 5-90 minutes. Thereby, the semi-finished product of the protective film with the predetermined pattern is cured to form a protective film.

The present invention will provide more details hereinafter in the following embodiments, but it should be understood that these examples are only illustrative and for illustrative purposes and should not be construed to limit the present invention.

### Synthesis Example

### Synthesis of Polysiloxane (B-1)

Following adding 0.05 mole of 3-(triethoxysilyl) propyl succinic anhydride (hereinafter referred to as GF-20), 0.05 mole of 3-glycidoxypropyltriethoxysilane (hereinafter referred to as GMATES), 0.30 mole of methyl trimethoxy silane (MTMS), 0.60 mole of phenyl trimethoxy silane (hereinafter referred to as PTMS), and 200 g of propylene glycol monoethyl ether (hereinafter referred to PGEE), into a 500 ml three-necked flask, an aqueous oxalic acid solution (0.40 g oxalic acid/75 g water) was added at room temperature with stirring within 30 minutes. Next, the flask was immersed in 30° C. oil bath and stirred for 30 minutes. Then, within 30 minutes, the temperature of the oil bath was raised to 120° C. After the solution temperature was dropped to 105° C., heating was resumed with stirring for polymerization for 6 hours. Then again, the solvent was removed using distillation to obtain the polysiloxane (B-1). The types and usage amounts of the raw materials of the polysiloxane (B-1) are shown in Table 1.

### Synthesis of Polysiloxane (B-2) to Polysiloxane (B-17)

The polysiloxane (B-2) to polysiloxane (B-17) was prepared by the same steps as synthesis of polysiloxane (B-1), and the difference thereof is: the type and the usage amount of the reaction mixture, the reaction temperature, and the polycondensation time of the polysiloxane were changed (as shown in Table 1). The abbreviations shown in Table 1 correspond to the compounds listed below.
GF-20 3-(triethoxysilyl) propyl succinic anhydride
DESDS (dimethoxysilyl)di(ethyl succinic anhydride)
TMSG 3-(trimethoxysilyl)propyl glutaric anhydride
GMATES 3-glycidoxypropyltriethoxysilane
TMSOX-D 2-oxetanylbutoxypropyltrimethoxysilane
ECETES 2-(3,4-epoxycyclohexyl)ethyltrimethoxysilane
TESOX-D 2-oxetanylbutoxypropyltriethoxysilane
TEOS tetraethoxysilane
TPOS tetraphenoxy silane
TMOS tetramethoxysilane
MTMS methyltrimethoxysilane
DMDMS dimethyldimethoxysilane
PTMS phenyltrimethoxysilane
PTES phenyltriethoxysilane
DMS-S27 SF-8427 (silanol terminated polysiloxane manufactured by Gelest Co., Ltd.)
PGEE propylene glycol monoethyl ether
DAA diacetone alcohol

### Synthesis of Polysiloxane (B-18)

Following adding 0.15 mole of methyl trimethoxy silane (MTMS), 0.55 mole of phenyl trimethoxy silane (hereinafter referred to as PTMS), 0.3 mole of 3-methacryloxypropyl trimethoxysilane (hereinafter referred to as MPTMS), and 200 g of propylene glycol monoethyl ether (hereinafter referred to PGEE), into a 500 ml three-necked flask, an aqueous oxalic acid solution (0.40 g oxalic acid/75 g water) was added at room temperature with stirring within 30 minutes. Next, the flask was immersed in 30° C. oil bath and stirred for 30 minutes. Then, within 30 minutes, the temperature of the oil bath was raised to 120° C. After the solution temperature was dropped to 105° C., heating was resumed with stirring for polymerization for 6 hours. Then again, the solvent was removed using distillation to obtain the polysiloxane (B-18).

TABLE 1

| Synthesis example | | | | B-1 | B-2 | B-3 | B-4 | B-5 | B-6 | B-7 | B-8 | B-9 |
|---|---|---|---|---|---|---|---|---|---|---|---|---|
| Composition | Silane | Silane | GF-20 | 0.05 | | | | 0.01 | 0.03 | | | 0.08 |
| | monomer | monomer | DESDS | | 0.10 | | 0.20 | | | 0.05 | | |
| | (mol) | (a-1) | TMSG | | | 0.15 | | | | | 0.10 | |
| | | Silane | GMATES | 0.05 | | | | | 0.07 | | 0.05 | |
| | | monomer | TMSOX-D | | | 0.20 | 0.30 | | | | | 0.12 |
| | | (a-2) | ECETES | | 0.10 | 0.20 | | 0.01 | | 0.10 | | |
| | | | TESOX-D | | 0.10 | | | | | | | |
| | | Silane | TEOS | | | | | | 0.50 | | 0.30 | |
| | | monomer | TPOS | | | | | | | 0.10 | | |
| | | (a-3) | TMOS | | | | | | | | 0.30 | 0.40 |
| | | | MTMS | 0.30 | | | 0.29 | 0.40 | 0.10 | 0.20 | | 0.40 |
| | | | DMDMS | | 0.40 | 0.20 | | | | | | |
| | | | PTMS | 0.60 | | 0.25 | | 0.58 | 0.30 | | 0.25 | |
| | | | PTES | | 0.30 | | 0.20 | | | 0.55 | | |
| | | other | DMS-S27 | | | | 0.01 | | | | | |
| | | compound | | | | | | | | | | |

| | | | | | | | | | | |
|---|---|---|---|---|---|---|---|---|---|---|
| Solvent (g) | PGEE | 200 | 100 | 200 | 200 | 200 | | | 200 | 200 |
| | DAA | | 100 | | | | 200 | 200 | | |
| Catalyst (g) | water | 75 | 75 | 75 | 75 | 75 | 75 | 75 | 75 | 75 |
| | Oxalic | 0.40 | 0.40 | 0.35 | 0.45 | 0.40 | 0.40 | 0.40 | 0.40 | 0.40 |
| | acid | | | | | | | | | |

| | | | | | | | | | |
|---|---|---|---|---|---|---|---|---|---|
| Reaction temp. (°C) | 105 | 110 | 105 | 110 | 110 | 105 | 105 | 110 | 105 |
| Polymerization time (hour) | 6 | 5 | 6 | 6 | 5 | 6 | 6 | 5 | 6 |

| Synthesis example | | | | B-10 | B-11 | B-12 | B-13 | B-14 | B-15 | B-16 | B-17 |
|---|---|---|---|---|---|---|---|---|---|---|---|
| Composition | Silane | Silane | GF-20 | | 0.005 | | 0.10 | | | | |
| | monomer | monomer | DESDS | 0.03 | | 0.25 | | 0.05 | 0.05 | | |
| | (mol) | (a-1) | TMSG | | | | | | | | |
| | | Silane | GMATES | | 0.02 | | | | | | |
| | | monomer | TMSOX-D | | 0.03 | | 0.005 | | | 0.30 | |
| | | (a-2) | ECETES | 0.02 | | 0.20 | | 0.45 | | | |
| | | | TESOX-D | | | | | | | | |
| | | Silane | TEOS | | 0.10 | 0.10 | | | | | |
| | | monomer | TPOS | 0.10 | | 0.10 | | 0.30 | | | |
| | | (a-3) | TMOS | 0.10 | | | 0.30 | | | | |
| | | | MTMS | | 0.30 | | 0.20 | | 0.45 | | |
| | | | DMDMS | 0.30 | | | | | | 0.50 | 0.50 |
| | | | PTMS | 0.45 | | 0.35 | 0.395 | 0.20 | | | 0.30 |
| | | | PTES | | 0.545 | | | | 0.50 | 0.20 | 0.20 |
| | | other | DMS-S27 | | | | | | | | |
| | | compound | | | | | | | | | |

| | | | | | | | | | |
|---|---|---|---|---|---|---|---|---|---|
| Solvent (g) | PGEE | 200 | 200 | 200 | | 200 | 200 | 100 | 100 |
| | DAA | | | | 200 | | | 100 | 100 |
| Catalyst (g) | water | 75 | 75 | 75 | 75 | 75 | 75 | 75 | 75 |
| | Oxalic | 0.40 | 0.40 | 0.35 | 0.40 | 0.40 | 0.40 | 0.40 | 0.40 |
| | acid | | | | | | | | |

| | | | | | | | | |
|---|---|---|---|---|---|---|---|---|
| Reaction temp. (°C) | 110 | 105 | 110 | 110 | 110 | 110 | 105 | 105 |
| Polymerization time (hour) | 6 | 5 | 5 | 6 | 5 | 5 | 6 | 6 |

### EXAMPLE

### Example 1

100 parts by weight of polysiloxane (B-1), 1 parts by weight of o-naphthoquinone diazide sulfonate (C-1) (trade name “DPAP200”, manufactured by DKC, the average degree of esterification being 67%) formed by 1-[1-(4-hydroxyphenyl)isopropyl)-4-(1,1-bis(4-hydroxyphenyl)ethyl)benzene and o-naphthoquinone diazide-5-sulfonic acid, and 0.005 parts by weight of 8-hydroxyquinoline (A-1) were added to 100 parts by weight of propylene glycol methyl ether acetate (D-1), and stirred using the shaking type stirrer until homogeneous, to obtain the photosensitive polysiloxane composition of Example 1.

The photosensitive polysiloxane composition was coated onto the untreated glass substrate (100 mm×100 mm×0.7 mm) by spin coating to form a coating film of about 2 μM thickness. Subsequently, the coating film was pre-baked at 110° C. for 2 minutes. The positive photoresist mask is then placed between the exposure machine and the coating film. Subsequently, the coating film is exposed to UV from the exposure machine with an exposure energy of 100 mJ/cm². The unwanted portions of the exposed coating film were removed by immersing the exposed coating film in 2.38% TMAH aqueous solution at 23° C. for 60 seconds. The plain glass substrate was then washed with water. Then again, the developed coating film was directly irradiated by the exposure machine with an exposure energy of 200 mJ/cm². Finally, the coating film was baked at oven under 230° C. for 60 minutes, the protective film and the plain glass substrate with the protective film can be obtained.

The evaluation results for the adhesion of the protective film and the plain glass substrate of the above-described Example 1 are shown in Table 3.

### Examples 2 to 16 and Comparative Examples 1 to 5

For Examples 2 to 16 and Comparative Examples 1 to 5, the photosensitive polysiloxane composition, the protective film and the plain glass substrate having the protective film are prepared with the same steps as in Example 1, and the differences lie in that: the types of the raw materials and their usage amounts are changed (as shown in Table 3). In addition, the evaluation results for the adhesion of the protective film and the plain glass substrate are shown in Table 3. The numerals shown in Table 3 correspond to the compounds listed in Table 2.

TABLE 2

| | |
|---|---|
| A-1 | 8-hydroxyquinoline |
| A-2 | 8-acetyloxyquinoline |
| A-3 | 4-hydroxypteridin |
| A-4 | 2,4-dihydroxypteridine |
| A-5 | 1,10-phenanthroline |
| A-6 | 5,6-dimethyl-1,10-phenanthroline |
| A-7 | 2,2′-bipyridyl |
| A-8 | 2,2′-bipyridyl-5-carboxylic acid |
| C-1 | o-naphthoquinone diazide sulfonate formed by 1-[1-(4- |
| | hydroxyphenyl) isopropyl]-4[1,1-bis(4-hydroxyphenyl) ethyl] |
| | benzene and o-naphthoquinone diazide 5-sulfonic acid |
| C-2 | o-naphthoquinone diazide sulfonate formed by 2,3,4-trihydroxy- |
| | benzophenone and o-naphthoquinone diazide 5-sulfonic acid |
| C-3 | o-naphthoquinone diazide sulfonate formed by |
| | 2,3,4,4′-tetrahydroxybenzophenone |
| D-1 | propylene glycol monomethyl ether acetate (PGMEA) |
| D-2 | 4-hydroxy-4-methyl-2-pentanone (DAA) |
| D-3 | cyclohexanone |
| E-1 | SF-8427 (manufactured by Dow Corning Toray Silicone Co., |
| | Ltd., surfactant) |
| E-2 | 3-glycidoxypropyltrimethoxysilane (trade name of KBM403, |
| | manufactured by Shin-Etsu Chemical Company, adhesion |
| | auxiliary agent) |

### Comparative Example 6

The polysiloxane composition synthesized in Comparative Example 6 is a negative-type photosensitive composition. Specifically, the polysiloxane composition of Comparative Example 6 is prepared by uniformly mixing 100 parts by weight of polysiloxane alkyl (B-18), 3 parts by mass of 1-[9-ethyl-6-(2-methylbenzoyl)-9H-carbazol-3-yl]-ethanone-1-(o-acetyloxime) (product name Irgacure OXE02, manufactured by Asahi Kasei Chemicals Co., Ltd., as a radical polymerization initiator), diethylene glycol ethyl methyl ether (as a solvent), ethylene glycol monobutyl ether (as a solvent), 0.2 parts by weight of polysiloxane-based surfactant SH8400 (by Dow Corning Toray Co., Ltd. It is noted that the adhesion between the protective film formed by the photosensitive polysiloxane composition of Comparative Example 6 and the glass substrate was marked as “X”; and the result of taper angle was also marked as “X”.

### [Adhesion Evaluation]

The adhesion is evaluated based on .8.5.2 cross-hatched test of adhesion test methods JIS.K5400 (1900) 8.5. The protective films obtained in the above Examples and Comparative Examples were cut into 100 mesh grids by knife. Then, following tearing off the sticking tape from the film, the residual mesh grids were calculated. The smaller the number of shedding mesh grid is, which means better adhesion. According to the following evaluation criteria, six levels (0B to 5B) are used to evaluate the adhesion.

⊚: 5B;

◯: 4B;

Δ: 3B˜2B; and

X: 1B˜0B;

Where, 5B: without any mesh grid torn off;

4B: 0%<the shedding quantity of mesh grids≦5%;

3B: 5%<the shedding quantity of mesh grids≦15%;

2B: 15%<the shedding quantity of mesh grids≦35%;

1B: 35%<the shedding quantity of mesh grids≦65%;

0B: 65%<the shedding quantity of mesh grids≦100%.

### [Taper Angle Evaluation]

The positive-type photosensitive polysiloxane composition was coated onto the untreated glass substrate (100 mm×100 mm×0.7 mm) by spin coating to form a coating film of about 2 μM thickness. Subsequently, the coating film was pre-baked at 110° C. for 2 minutes. The photoresist mask with line and space pattern (manufactured by Nippon Filcon Co., Ltd.) is then placed between the exposure machine and the coating film. Subsequently, the coating film is exposed to UV from the exposure machine (AG500-4N, manufactured by M&R Nano Technology Co., Ltd.) with an exposure energy of 100 mJ/cm². The unwanted portions of the exposed coating film were removed by immersing the exposed coating film in 2.38% TMAH aqueous solution at 23° C. for 60 seconds. The plain glass substrate was then washed with water. Finally, the coating film was baked at oven under 230° C. for 60 minutes, the plain glass substrate with pattern can be obtained. The taper angle is measured by taking SEM pictures of the cross section of the pattern, and measuring a taper angle θ between a side surface (the tapered surface) of the pattern and the substrate. The taper angle is evaluated according to the following evaluation criteria.

⊚: 60°<θ≦90°;

◯: 50°<θ≦60°;

Δ: 40°<θ≦50°; and

X: θ≦40°.

### [Evaluation Results]

As shown in Table 3, compared with the photosensitive polysiloxane compositions of Comparative Example 1 to Comparative Example 3 as well as the photosensitive polysiloxane composition of Comparative Example 4 without the nitrogen-containing heterocyclic compound (A), the photosensitive polysiloxane compositions of Examples 1 to 8 contain the nitrogen-containing heterocyclic compound (A), and provide better adhesion between the protective film thereof and the plain glass substrate. These results show that using the nitrogen-containing heterocyclic compound (A) as a starting material in the photosensitive polysiloxane composition can increase the adhesion between the protective film thereof and the plain glass substrate. In addition, the photosensitive polysiloxane composition of Example 3 further includes 3 parts by weight of 3-epoxypropoxypropyl trimethoxysilane (adhesion auxiliary agent). Accordingly, the protective film of Example 3 provides better adhesion toward the glass substrate compared to the other embodiment examples and comparative examples.

TABLE 3

| | | Examples | | | | | | | | | | |
|---|---|---|---|---|---|---|---|---|---|---|---|---|
| Ingredient | | 1 | 2 | 3 | 4 | 5 | 6 | 7 | 8 | 9 | 10 | 11 |
| nitrogen-containing | A-1 | 0.005 | | | | | | | | | 0.3 | |
| heterocyclic | A-2 | | 0.01 | | | | | | | 1 | | |
| compound (A) | A-3 | | | 0.05 | | | | | | | 0.2 | |
| (parts by weight) | A-4 | | | | 0.1 | | | | | | | 0.03 |
| | A-5 | | | | | 0.5 | | | | | | |
| | A-6 | | | | | | 1 | | | | | |
| | A-7 | | | | | | | 3 | | | | |
| | A-8 | | | | | | | | 5 | | | 0.05 |
| polysiloxane (B) | B-1 | 100 | | | | | | | | | | |
| (parts by weight) | B-2 | | 100 | | | | | | | | | |
| | B-3 | | | 100 | | | | | | | | |
| | B-4 | | | | 100 | | | | | | | |
| | B-5 | | | | | 100 | | | | | | |
| | B-6 | | | | | | 100 | | | | | |
| | B-7 | | | | | | | 100 | | | | |
| | B-8 | | | | | | | | 100 | | | |
| | B-9 | | | | | | | | | 100 | | |
| | B-10 | | | | | | | | | | 100 | |
| | B-11 | | | | | | | | | | | 100 |
| | B-12 | | | | | | | | | | | |
| | B-13 | | | | | | | | | | | |
| | B-14 | | | | | | | | | | | |
| | B-15 | | | | | | | | | | | |
| | B-16 | | | | | | | | | | | |
| | B-17 | | | | | | | | | | | |
| o-naphthoquinone | C-1 | 1 | 5 | 10 | | 20 | 5 | 15 | 15 | 30 | 5 | 10 |
| diazide | C-2 | | | | 15 | | 20 | | 35 | 10 | | |
| sulfonate (C) | C-3 | | | | | | | 15 | | | 5 | |
| (parts by weight) | | | | | | | | | | | | |
| solvent (D) | D-1 | 100 | 300 | 300 | 300 | | 300 | 500 | 600 | 800 | 300 | |
| (parts by weight) | D-2 | | | | 200 | 500 | | 300 | | | | 500 |
| | D-3 | | | | | | 300 | 200 | | | | |
| additive (E) | E-1 | | | | | | 1 | | | | | |
| (parts by weight) | E-2 | | | | 3 | | | | | | | |
| Test | Adhesion | ◯ | ◯ | ◯ | ◯ | ◯ | ◯ | ◯ | ◯ | ◯ | ◯ | ◯ |
| | Taper | ◯ | ◯ | ◯ | ◯ | ◯ | ⊚ | ⊚ | ⊚ | ⊚ | ⊚ | ◯ |
| | angle | | | | | | | | | | | |

| | | Examples | | | | | Comparative Example | | | | |
|---|---|---|---|---|---|---|---|---|---|---|---|
| Ingredient | | 12 | 13 | 14 | 15 | 16 | 1 | 2 | 3 | 4 | 5 |
| nitrogen-containing | A-1 | | | | | | | | | 0.1 | |
| heterocyclic | A-2 | 0.01 | 0.2 | | 3 | 0.2 | | 0.05 | | | |
| compound (A) | A-3 | | | | | | | | | | |
| (parts by weight) | A-4 | | | 5 | | | | | | | |
| | A-5 | | | | | | | | 0.1 | | |
| | A-6 | 0.01 | | | | | | | | | |
| | A-7 | | | | | 0.3 | | | | | |
| | A-8 | | | | | | | | | | |
| polysiloxane (B) | B-1 | | | | 50 | | | | | | |
| (parts by weight) | B-2 | | | | | 70 | 100 | | | | |
| | B-3 | | | | | | | | | | |
| | B-4 | | | | | | | | | | |
| | B-5 | | | | | | | | | | |
| | B-6 | | | | | | | | | | |
| | B-7 | | | | | | | | | | |
| | B-8 | | | | 50 | | | | | | |
| | B-9 | | | | | | | | | | |
| | B-10 | | | | | | | | | | |
| | B-11 | | | | | 30 | | | | | |
| | B-12 | 100 | | | | | | | | | |
| | B-13 | | 100 | | | | | | | | |
| | B-14 | | | 100 | | | | | | | |
| | B-15 | | | | | | | 100 | | | |
| | B-16 | | | | | | | | 100 | | |
| | B-17 | | | | | | | | | 100 | 100 |
| o-naphthoquinone | C-1 | 20 | 10 | 10 | | 10 | 15 | | | 15 | 20 |
| diazide | C-2 | | | 5 | | | | 15 | | | |
| sulfonate (C) | C-3 | | | | 10 | | | | 15 | | |
| (parts by weight) | | | | | | | | | | | |
| solvent (D) | D-1 | | 300 | 500 | 200 | 500 | 300 | | 500 | 500 | 500 |
| (parts by weight) | D-2 | | | | | | | 500 | | | |
| | D-3 | 300 | | | | | | | | | |
| additive (E) | E-1 | | | | | | | | | | |
| (parts by weight) | E-2 | | | | | | | | | | |
| Test | Adhesion | ◯ | ◯ | ◯ | ◯ | ◯ | X | X | X | X | X |
| | Taper | ◯ | ◯ | ◯ | ⊚ | ◯ | X | X | X | X | X |
| | angle | | | | | | | | | | |

In summary, by using the photosensitive polysiloxane composition having the nitrogen-containing heterocyclic compound (A) to form a protective film, the present invention solves the problem of insufficient adhesion as a protective film formed between the elements to be protected and unsatisfactory taper angle by using the conventional light-curing polysiloxane composition. Further, by using the photosensitive polysiloxane composition having the polysiloxane (B) obtained by monomer containing silane monomer (b-1) or silane monomer (b-2) to form a protective film, the present invention solves the prior problem of insufficient adhesion and unsatisfactory taper angle by using the conventional light-curing polysiloxane composition. In addition, by using the photosensitive polysiloxane composition having the polysiloxane (B) obtained by monomer containing silane monomer (b-3-1), the films with satisfactory taper angles can be obtained.

While the invention has been described and illustrated with reference to specific embodiments thereof, these descriptions and illustrations do not limit the invention. It should be understood by those skilled in the art that various changes may be made and equivalents may be substituted without departing from the true spirit and scope of the invention as defined by the appended claims. The illustrations may not be necessarily being drawn to scale. There may be distinctions between the artistic renditions in the present disclosure and the actual apparatus due to manufacturing processes and tolerances. There may be other embodiments of the present invention which are not specifically illustrated. The specification and the drawings are to be regarded as illustrative rather than restrictive. Modifications may be made to adapt a particular situation, material, composition of matter, method, or process to the objective, spirit and scope of the invention. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the invention.

What is claimed is:

1. A photosensitive polysiloxane composition, comprising
a nitrogen-containing heterocyclic compound (A),
a polysiloxane (B),
an o-naphthoquinone diazide sulfonate (C), and
a solvent (D), wherein the nitrogen-containing heterocyclic compound (A) is selected from the group consisting of compounds represented by formulas (1) to (4): 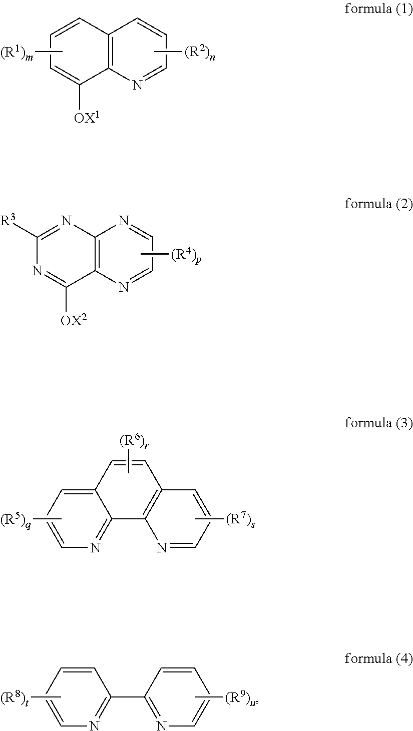
wherein in the formulas (1) to (4), X¹ and X² each independently represents hydrogen, an acyl or an alkyl group; R¹ to R⁹ each independently represents hydrogen, a hydroxyl group, a carboxyl group, a sulfo group, an alkyl group, an amino group, halogen or a mercapto group; m, n, q and s each independently represents an integer selected from 0, 1, 2 and 3; p and r each independently represents an integer selected from 0, 1 and 2; t and u each independently represents an integer selected from 0, 1, 2, 3 and 4;
the polysiloxane (B) is a copolymer formed by polycondensation of a mixture comprising a silane monomer (b-1) represented by formula (5), a silane monomer (b-2) represented by formula (7), and a silane monomer (b-3) represented by formula (8):
Si(R¹⁰)_{w}(OR¹¹)_{4-w} formula (5),
wherein, in the formula (5), R¹⁰ represents hydrogen, an alkyl group of 1-10 carbon atoms, an alkenyl group of 2-10 carbon atoms, an aryl group of 6-15 carbon atoms, an alkyl group containing an acid anhydride group, an alkyl group containing an epoxy group, an alkoxy group containing an epoxy group, and R¹⁰ comprises at least one alkyl group containing an acid anhydride group, and for more than one R¹⁰, R¹⁰ are the same or different; R¹¹ represents hydrogen, an alkyl group of 1-6 carbon atoms, an acyl group of 1-6 carbon atoms, an aryl group of 6-15 carbon atoms, and for more than one R¹¹, R¹¹ are the same or different; w represents an integer selected from 1, 2 and 3;
Si(R⁷⁰)ᵥ(OR⁷¹)₄₋ᵥ formula (7),
wherein, in the formula (7), R⁷⁰ represents hydrogen, an alkyl group of 1-10 carbon atoms, an alkenyl group of 2-10 carbon atoms, an aryl group of 6-15 carbon atoms, an alkyl group containing an acid anhydride group, an alkyl group containing an epoxy group, an alkoxy group containing an epoxy group, and R⁷¹ comprises at least one alkyl group containing an epoxy group or an alkoxy group containing an epoxy group, and for more than one R⁷⁰, R⁷⁰ are the same or different; R⁷¹ represents hydrogen, an alkyl group of 1-6 carbon atoms, an acyl group of 1-6 carbon atoms, an aryl group of 6-15 carbon atoms, and for more than one R⁷¹, R⁷¹ are the same or different; v represents an integer selected from 1, 2 and 3; and
Si(R⁸⁰)_{f}(OR⁸¹)_{4-f} formula (8),
wherein, in the formula (8), R⁸⁰ represents hydrogen, an alkyl group of 1-10 carbon atoms, an alkenyl group of 2-10 carbon atoms, an aryl group of 6-15 carbon atoms; a plurality of R⁸⁰ may be the same or different; R⁸¹ represents hydrogen, an alkyl group of 1-6 carbon atoms, an acyl group of 1-6 carbon atoms, an aryl group of 6-15 carbon atoms, and for more than one R⁸¹, R⁸¹ are the same or different; f represents an integer selected from 0, 1, 2 and 3.

2. The composition of claim 1, wherein based on 1 mole of the total silane monomers in the mixture, a content of the silane monomer (b-1) is 0.01 moles to 0.20 moles, a content of the silane monomer (b-2) is 0.01 moles to 0.40 moles, and a content of the silane monomer (b-3) is 0.40 moles to 0.98 moles.

3. The composition of claim 1, wherein based on 100 parts by weight of the polysiloxane (B), a content of the nitrogen-containing heterocyclic compound (A) is 0.005 parts by weight to 40 parts by weight, a content of o-naphthoquinone diazide sulfonate (C) is 1 part by weight to 50 parts by weight, and a content of the solvent (D) is 100 parts by weight to 1000 parts by weight.

4. The composition of claim 1, wherein the silane monomer (b-3) further comprises a silane monomer (b-3-1) represented by formula (8-1):
Si(OR⁸²)₄ formula (8-1),
wherein, in the formula (8-1), R⁸² represents hydrogen, an alkyl group of 1-6 carbon atoms, an acyl group of 1-6 carbon atoms, an aryl group of 6-15 carbon atoms, and R⁸² are the same or different for more than one R⁸².

5. The composition of claim 4, wherein based on 1 mole of the total silane monomers in the mixture, a content of the silane monomer (b-3-1) is 0.10 moles to 0.60 moles.

6. A protective film, comprising the photosensitive polysiloxane composition of claim 1.

7. The protective film of claim 6, wherein the protective film is a planarization film or an interlayer insulation film for substrates of liquid crystal displays or organic electro-luminescence displays, or a protective film for optical waveguide core materials or coating materials.

8. A device having a protective film of claim 6 covering thereon.

9. A protective film, comprising the photosensitive polysiloxane composition of claim 4.

10. The protective film of claim 9, wherein the protective film is a planarization film or an interlayer insulation film for substrates of liquid crystal displays or organic electro-luminescence displays, or a protective film for optical waveguide core materials or coating materials.

11. A device having a protective film of claim 9 covering thereon.

12. A film forming method, comprising:
forming a film on substrate by applying a photosensitive polysiloxane composition of claim 1 on the substrate.

13. A film forming method, comprising:
forming a film on substrate by applying a photosensitive polysiloxane composition of claim 4 on the substrate.
